(19) United States
(12) Patent Application Publication
(10) Pub. No.: US 2020/0335431 A1
(43) Pub. Date: Oct. 22, 2020

(54) SEMICONDUCTOR DEVICE PACKAGE

(71) Applicant: Advanced Semiconductor Engineering, Inc., Kaohsiung (TW)

(72) Inventors: Min-Fong SHU, Kaohsiung (TW); Yi-Hsiu TSENG, Kaohsiung (TW)

(73) Assignee: Advanced Semiconductor Engineering, Inc., Kaohsiung (TW)

(21) Appl. No.: 16/921,663

(22) Filed: Jul. 6, 2020

Related U.S. Application Data
(63) Continuation of application No. 15/687,076, filed on Aug. 25, 2017.
(60) Provisional application No. 62/385,791, filed on Sep. 9, 2016.

(51) Int. Cl. H01L 23/495; H01L 23/31; H01L 21/56; H01L 21/48

(52) U.S. Cl. CPC H01L 23/49586; H01L 23/49582; H01L 23/3114; H01L 21/56; H01L 21/4835; H01L 24/32; H01L 23/3142; H01L 2224/48091; H01L 2224/48106; H01L 2224/32245; H01L 23/49541

(57) ABSTRACT

A semiconductor device package includes a copper lead frame, a copper oxide compound layer and an encapsulant. The copper oxide compound layer is in contact with a surface of the copper lead frame. The copper oxide compound layer includes a copper(II) oxide, and a thickness of the copper oxide compound layer is in a range from about 50 nanometers to about 100 nanometers. The encapsulant is in contact with a surface of the copper oxide compound layer.

### CROSS-REFERENCE TO RELATED APPLICATIONS

This application is a continuation of U.S. patent application Ser. No. 15/687,076 filed Aug. 25, 2017, which claims the benefit of and priority to U.S. Provisional Application No. 62/385,791, filed Sep. 9, 2016, the content of which is incorporated herein by reference in its entirety.

### BACKGROUND

### 1. Technical Field

The present disclosure relates to a semiconductor device package including a lead frame and an encapsulant, and to providing for adhesion between the lead frame and the encapsulant.

### 2. Description of the Related Art

A copper lead frame (e.g. a lead frame that includes at least some copper) is a component in some semiconductor device packages. Some comparative semiconductor device packages, however, may experience delamination issues due to poor adhesion strength between the copper lead frame and an encapsulant.

### SUMMARY

In some embodiments, a semiconductor device package includes a copper lead frame, a copper oxide compound layer and an encapsulant. The copper oxide compound layer is in contact with a surface of the copper lead frame. The copper oxide compound layer includes a copper(II) (Cu(II)) oxide, and a thickness of the copper oxide compound layer is in a range from about 50 nanometers to about 100 nanometers. The encapsulant is in contact with a surface of the copper oxide compound layer.

In some embodiments, a semiconductor device package includes a copper lead frame, a copper oxide compound layer and an encapsulant. The copper oxide compound layer is disposed on a surface of the copper lead frame, wherein the copper oxide compound layer includes a Cu(II) oxide and a copper(I) (Cu(I)) oxide, and a ratio of Cu(II) to Cu(I) of the copper oxide compound layer is equal to or greater than 1. The encapsulant is in contact with a surface of the copper oxide compound layer.

In some embodiments, a semiconductor device package includes a copper lead frame, a copper oxide compound layer and an encapsulant. The copper oxide compound layer is disposed on the copper lead frame. The encapsulant is in contact with a surface of the copper oxide compound layer, wherein a shear force at a contact interface between the copper oxide compound layer and the encapsulant measured at room temperature is substantially equal to or greater than 6 kilograms.

### BRIEF DESCRIPTION OF THE DRAWINGS

Some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 is a cross-sectional view of some embodiments of a semiconductor device package in accordance with an aspect of the present disclosure.

FIG. 2 is a schematic view of some embodiments illustrating bonding between a copper oxide compound layer and an encapsulant in accordance with another aspect of the present disclosure.

FIG. 3 is a flow chart of some embodiments illustrating a method of manufacturing a semiconductor device package in accordance with another aspect of the present disclosure.

FIG. 4 shows an experimental result of shear forces and delamination rates in accordance with another aspect of the present disclosure.

FIG. 5 shows an experimental result of shear forces at room temperature in accordance with another aspect of the present disclosure.

FIG. 6 shows an experimental result of shear forces at high temperature in accordance with another aspect of the present disclosure.

FIG. 7 is a flow chart of some embodiments illustrating a method of manufacturing a semiconductor device package in accordance with another aspect of the present disclosure.

FIG. 8 shows an experimental result of shear forces at room temperature in accordance with another aspect of the present disclosure.

FIG. 9 is a flow chart of some embodiments illustrating a method of manufacturing a semiconductor device package in accordance with another aspect of the present disclosure.

FIG. 10 is a schematic diagram of some embodiments illustrating a method of manufacturing a semiconductor device package in accordance with another aspect of the present disclosure.

FIG. 11 shows an experimental result of shear forces at room temperature in accordance with another aspect of the present disclosure.

FIG. 12 shows an experimental result of shear forces at room temperature in accordance with another aspect of the present disclosure.

FIG. 13 shows an experimental result of shear forces at high temperature in accordance with another aspect of the present disclosure.

### DETAILED DESCRIPTION

The following disclosure provides different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Descriptions of shear force in the following description may refer to a magnitude of the shear force in kilograms. This refers to a force having a magnitude equal to a magnitude of a gravitational force on the specified number of kilograms exerted by the Earth at a surface of the Earth (e.g. at sea level).

The following description includes description of some semiconductor device packages, and methods of manufacturing thereof. In some embodiments of the present disclosure, the semiconductor device package includes a copper oxide compound layer including Cu(II) oxide (CuO) and Cu(I) oxide (Cu₂O), and the ratio of Cu(II) oxide to Cu(I) oxide is equal to or greater than about 1. In some embodiments, the ratio of Cu(II) oxide to Cu(I) oxide of a first portion of the copper oxide compound layer proximate to an interface between an encapsulant and the copper oxide compound layer is less than that of a second portion of the copper oxide compound layer distant from the interface relative to the first portion. As discussed below, in some implementations, the copper oxide compound layer including Cu(II) oxide and Cu(I) oxide can provide for significantly increased adhesion strength of the copper lead frame to the encapsulant, as compared to some comparative implementations. Semiconductor device packages of the present disclosure can provide for advantages such as being unlikely to delaminate and high reliability. The following description further includes description of some methods for manufacturing semiconductor device packages. The methods may include performing a back-end (also referred to herein as “BE”) baking process, a back-end plasma clean or a combination thereof on the copper oxide compound layer.

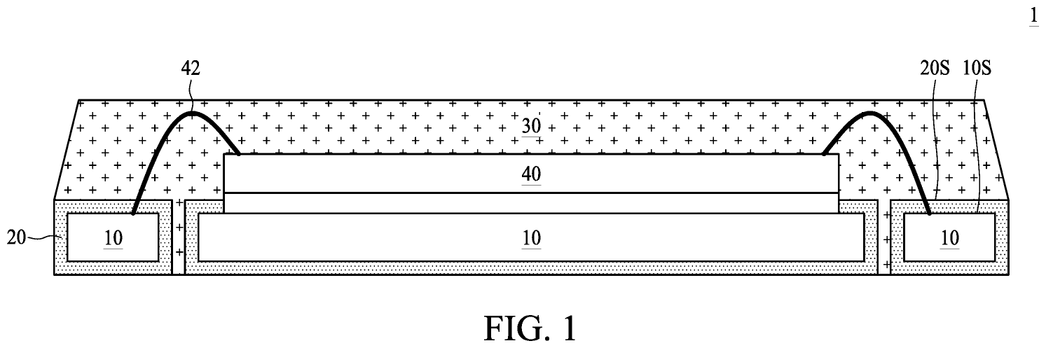

FIG. 1 is a cross-sectional view of some embodiments of a semiconductor device package 1 in accordance with an aspect of the present disclosure. As shown in FIG. 1, the semiconductor device package 1 includes a copper lead frame 10, a copper oxide compound layer 20 and an encapsulant 30. In some embodiments, the material of the copper lead frame 10 includes copper, a copper alloy or a combination thereof. In some embodiments, the copper oxide compound layer 20 is disposed on the copper lead frame 10. In some embodiments, the copper oxide compound layer 20 is disposed on and in contact with a surface 10S of the copper lead frame 10. In some embodiments, the copper oxide compound layer 20 includes a Cu(II) oxide (e.g. cupric oxide (CuO)). In some embodiments, the copper oxide compound layer 20 may have a first surface in contact with the surface 10S of the copper lead frame 10, and a second surface 20S opposite to the first surface. In some embodiments, the encapsulant 30 is in contact with the surface 20S of the copper oxide compound layer 20. In some embodiments, the material of the encapsulant 30 may include an organic material such as an epoxy resin. In some embodiments, the semiconductor device package 1 may further include at least one semiconductor die 40 disposed between the copper oxide compound layer 20 and the encapsulant 30. The at least one semiconductor die 40 is electrically connected to the copper lead frame 10. In some embodiments, the semiconductor die 40 is electrically connected to the copper lead frame 10 through bonding wires 42, but other electrical connections may be implemented additionally or alternatively.

In some embodiments, the copper oxide compound layer 20 may further include Cu(I) oxide, (e.g. cuprous oxide (Cu₂O)). In the copper oxide compound layer 20, the amount of cupric oxide may be about equal to or greater than the amount of cuprous oxide included in the copper oxide compound layer 20, that is, the ratio of Cu(II) to Cu(I) of the copper oxide compound layer 20 is equal to or greater than about 1, such as about 1.2 or greater, about 1.5 or greater, about 2 or greater, or about 3 or greater. In some embodiments, the ratio of Cu(II) to Cu(I) refers to a ratio of an atomic percentage of copper atoms in the II or 2+ oxidation state relative to an atomic percentage of copper atoms in the I or 1+ oxidation state. In some embodiments, the ratio of Cu(II) to Cu(I) of a first portion of the copper oxide compound layer 20 distant from the surface 10S of the copper lead frame 10 is higher than the ratio of Cu(II) to Cu(I) of a second portion of the copper oxide compound layer 20 proximate to the surface 10S of the copper lead frame 10, such as about 1.2 times or greater, about 1.5 times or greater, about 2 times or greater, or about 3 times or greater. The ratio of Cu(II) to Cu(I) of the copper oxide compound layer 20 may increase (e.g. may increase monotonically) along a direction from the surface 10S to the surface 20S.

In some embodiments, the thickness of the copper oxide compound layer 20 (e.g. a thickness of the copper oxide compound layer 20 disposed on the surface 10S of the copper lead frame 10) is in a range from about 10 nanometers to about 150 nanometers or from about 50 nanometers to about 100 nanometers. In some embodiments, a shear force at a contact interface between the copper oxide compound layer 20 and the encapsulant 30 measured at room temperature (e.g., at about 25° C.) is substantially equal to or greater than about 6 kilograms. In some embodiments, the shear force between the copper oxide compound layer 20 and the encapsulant 30 may be proportional to the thickness of the copper oxide compound layer 20. By way of example, the shear force at the contact interface between the copper oxide compound layer 20 and the encapsulant 30 measured at room temperature is substantially equal to or greater than about 7 kilograms when the thickness of the copper oxide compound layer 20 is equal to or greater than about 65 nanometers. By way of example, the shear force at the contact interface between the copper oxide compound layer 20 and the encapsulant 30 measured at room temperature is substantially equal to or greater than about 11 kilograms when the thickness of the copper oxide compound layer 20 is equal to or greater than about 70 nanometers.

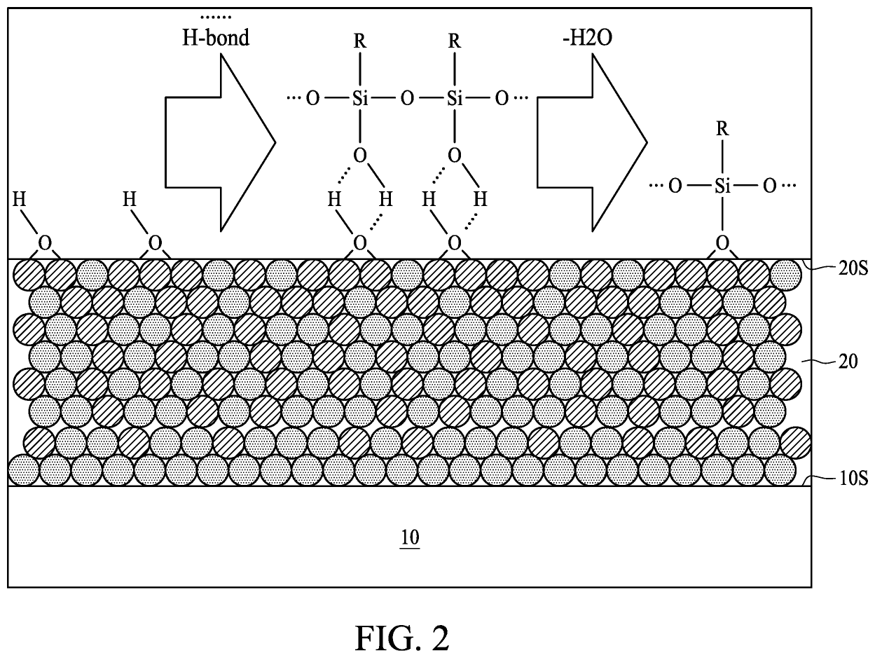

FIG. 2 is a schematic view of some embodiments illustrating bonding between a copper oxide compound layer and an encapsulant in accordance with another aspect of the present disclosure. As depicted in FIG. 2, in contrast to cuprous oxide in a substantially fully oxidized state, which may have some stereoscopic impediments, cupric oxide in a semi-oxidized state can be implemented and can be exposed to oxygen. Therefore, the implemented cupric oxide is more active than might otherwise be the case, and can form more hydrogen bonds with hydrogen atoms of promotors such as silicon hydroxide (SiOH) in the encapsulant 30 (also referred to as encapsulant molding compound EMC). After dehydration, the cupric oxide can help to enhance adhesion strength between the copper lead frame 10 and the encapsulant 30.

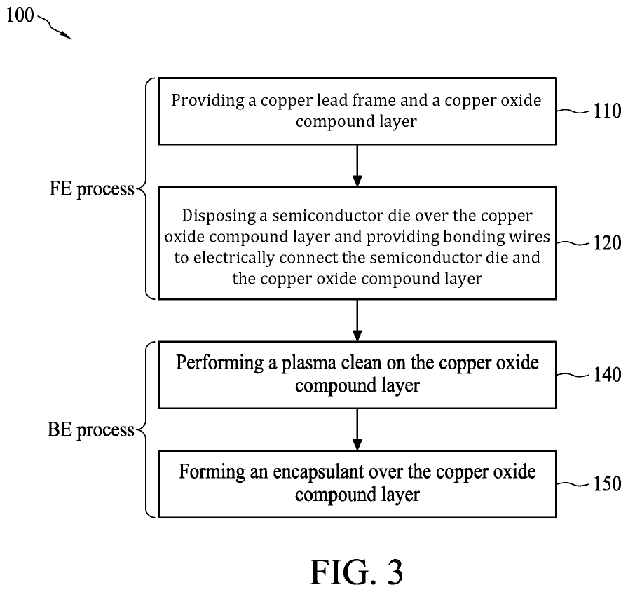

FIG. 3 is a flow chart of some embodiments illustrating a method of manufacturing a semiconductor device package in accordance with another aspect of the present disclosure. Referring to FIG. 3, the method 100 begins with an operation 110 in which a copper lead frame 10 and a copper oxide compound layer 20 are provided. In some embodiments, the copper oxide compound layer 20 may be formed on the copper lead frame 10 by exposure in an oxygen-containing environment or by a front-end (also referred to herein as “FE”) baking process, which is performed prior to provision of the semiconductor die 40 and the bonding wires 42. In some embodiments, the thickness of the copper oxide compound layer 20 is less than about 50 nanometers after exposure to the oxygen-containing environment or the front-end baking process, such as about 40 nanometers or less, about 30 nanometers or less, about 20 nanometers or less, or about 10 nanometers or less. In some embodiments, the thickness of the copper oxide compound layer 20 is about 10 nanometers after exposure to the oxygen-containing environment or the front-end baking process. The method proceeds with an operation 120 in which a semiconductor die 40 is disposed on the copper oxide compound layer 20. In some embodiments, bonding wires 42 are provided to electrically connect the semiconductor die 40 to the copper lead frame 10 through the copper oxide compound layer 20. In some embodiments, operations 110 and 120 are referred to as front-end processes. The method proceeds with an operation 140 in which a plasma clean (a back-end plasma clean) is performed on the copper oxide compound layer 20. After the BE plasma clean, the thickness of the copper oxide compound layer 20 may remain substantially the same or may slightly increase, but still be less than about 50 nanometers. The method proceeds with an operation 150 in which an encapsulant 30 is formed over the copper oxide compound layer 20. In some embodiments, operations 140 and 150 are referred to as back-end processes.

The method 100 is merely an example, and is not intended to limit the present disclosure beyond what is explicitly recited in the claims. Additional operations can be provided before, during, and/or after the method 100, and some operations described can be replaced, eliminated, or re-ordered to provide for other embodiments of the method.

The plasma clean may be configured to clean and activate the surface 20S of the copper oxide compound layer 20. In some embodiments, process gas such as hydrogen gas (H₂) and other inert gas such as argon gas (Ar) may be introduced during the plasma clean. The plasma clean may be performed with a fixed or varied gas flow rate. An example process recipe of the plasma clean is illustrated as follows:

Plasma process time: in a range of about 10 to about 600 seconds;

Power: in a range of about 50 to about 1200 watts;

Gas ratio: H₂:Ar is in a range of about 5:95 to about 100:0;

Gas flow rate: in a range of about 10 to about 2000 standard cubic centimeters per minute (sccm); and

Vacuum pressure: in a range of about 0.02 mbar to about 1 bar.

In some embodiments, the plasma clean is performed on a batch of copper lead frames 10 stored in a slot cartridge for which lateral sides of the cartridge are open. Accordingly, the lateral sides of the copper lead frames 10 may be exposed to the plasma to enhance a plasma clean effect. The plasma clean is performed, for example, to activate the copper oxide compound layer 20. In some embodiments, the plasma clean is performed to initiate CuO reduction and Cu₂O oxidation, so as to generate more CuO from Cu₂O. In some embodiments, the surface activation, CuO reduction and Cu₂O oxidation may involve the following chain reactions.

2CuO+H₂→Cu₂O+H₂O (1)

Cu₂O+H₂O→2CuO—H (2)

Cu₂O+H₂→2Cu+H₂O (3)

The activated CuO may readily generate more hydrogen bonds with hydrogen atoms of promotors such as silicon hydroxide (SiOH) in the encapsulant 30. Accordingly, adhesion strength between the copper lead frame 10 and the encapsulant 30 may be enhanced.

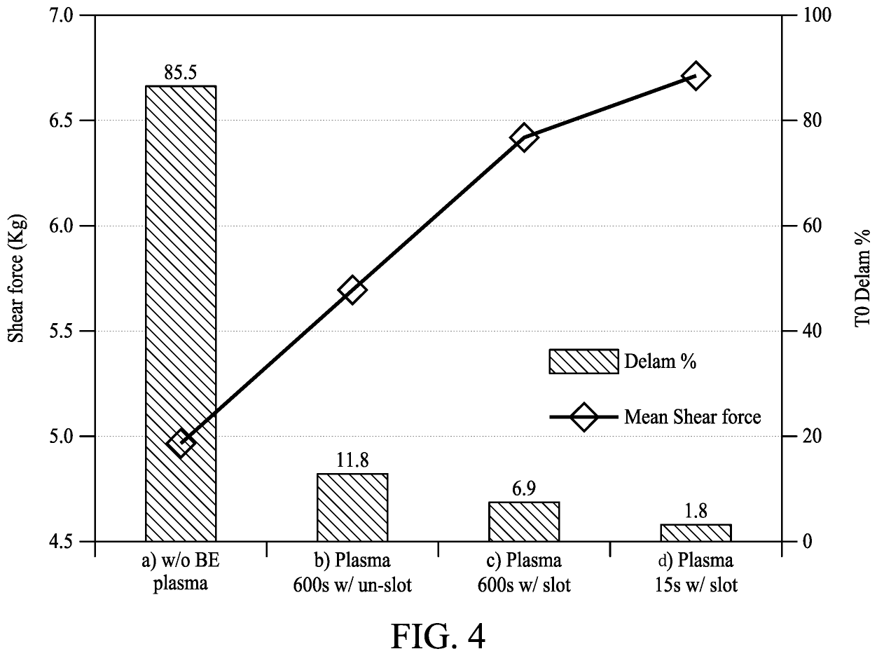

FIG. 4 shows an experimental result of shear forces and delamination rates (percentage of products that exhibit delamination, or likelihood of exhibiting delamination) in accordance with another aspect of the present disclosure, wherein sample “a” includes semiconductor device packages that have not undergone a BE plasma clean; sample “b” includes semiconductor device packages that have undergone BE plasma clean for a longer plasma process time (600 seconds) in an un-slotted cartridge; sample “c” includes semiconductor device packages that have undergone BE plasma clean for a longer plasma process time (600 seconds) in a slot cartridge; and sample “d” includes semiconductor device packages that have undergone BE plasma clean for a shorter plasma process time (15 seconds) in a slotted cartridge. As shown in FIG. 4, the experimental result shows that the shear force of the semiconductor device packages that have undergone a plasma clean (samples b, c and d) is higher than that of the semiconductor device packages that have not undergone a plasma clean (sample a). The experimental result also shows that a delamination rate of a contact interface between the copper oxide compound layer 20 and the encapsulant 30 of the semiconductor device packages that have undergone a plasma clean (samples b, c and d) can be reduced to about 1.8%, or lower, which is a lower rate than that of the semiconductor device packages that have not undergone a plasma clean (sample a). As shown in FIG. 4, sample a has a delamination rate of about 85.5%. Sample b has a delamination rate of about 11.8%. Sample c has a delamination rate of about 6.9%. Sample d has a delamination rate of about 1.8%.

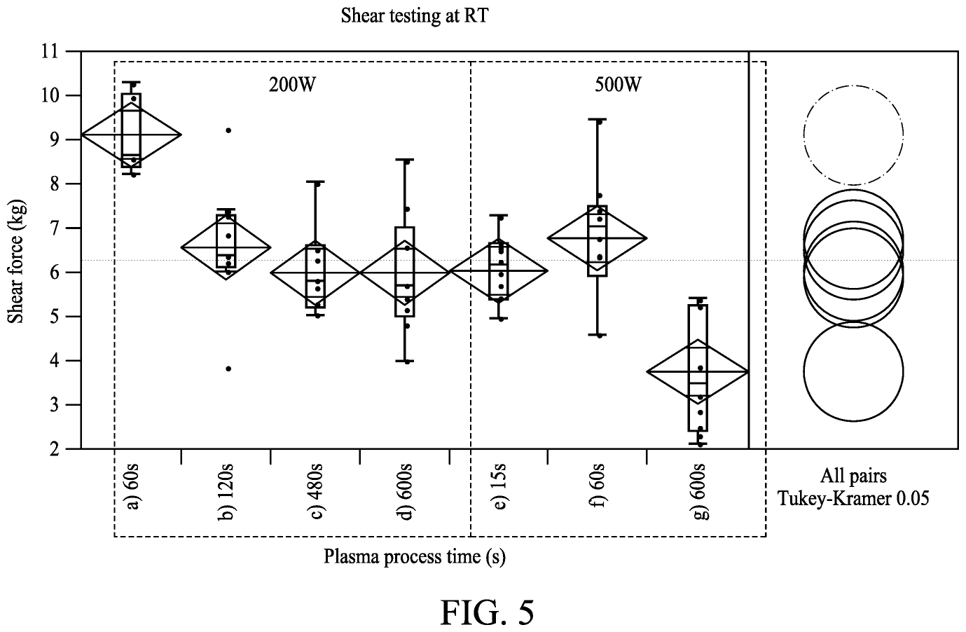

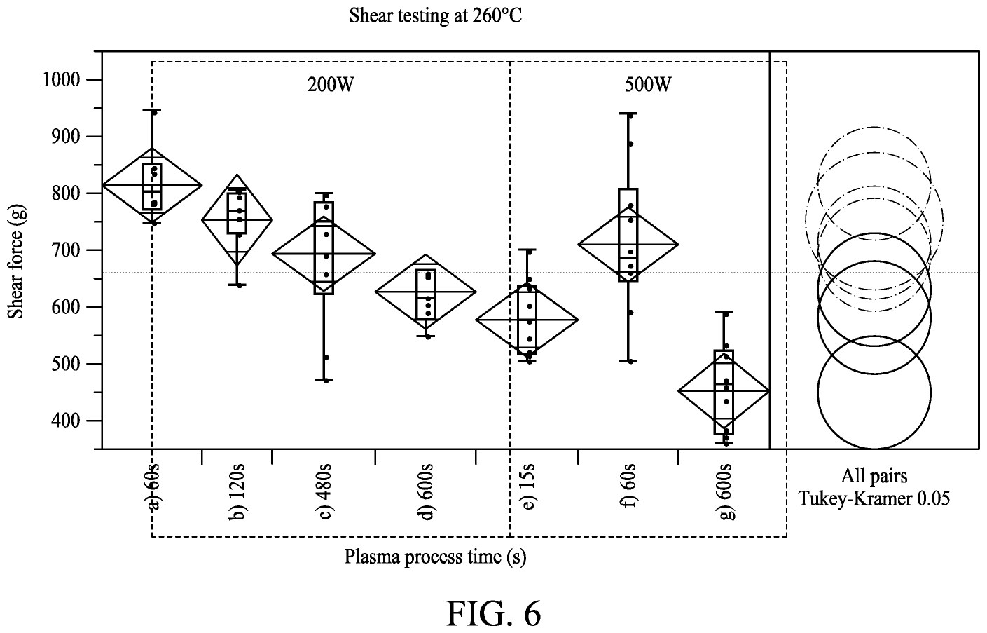

FIG. 5 shows an experimental result of shear forces at room temperature and corresponding all-pairs Tukey-Kramer data in accordance with another aspect of the present disclosure, and FIG. 6 shows an experimental result of shear forces at high temperature and corresponding all-pairs Tukey-Kramer data in accordance with another aspect of the present disclosure, wherein samples a through d include semiconductor device packages that have undergone a plasma clean at 200 watts for different periods of plasma process times, and samples e through g include semiconductor device packages that have undergone a plasma clean at 500 watts for different periods of plasma process times. As shown in FIG. 5 and FIG. 6, the experimental results show that the shear force of the semiconductor device packages that have undergone a plasma clean at lower power (e.g. 200 watts) tends to be larger than the shear force of the semiconductor device packages that have undergone a plasma clean at higher power (e.g. 500 watts), whether tested at room temperature or high temperature (e.g. at about 260° C. or greater). The experimental results also show that the shear force of the semiconductor device packages that have undergone a plasma clean with a shorter plasma process time tends to be larger than the shear force of the semiconductor device packages that have undergone a plasma clean with a longer plasma process time, whether tested at room temperature or high temperature (e.g. at about 260° C. or greater).

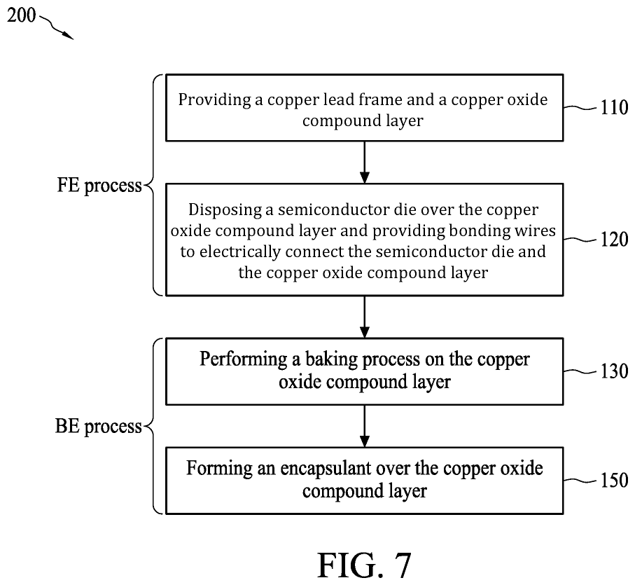

FIG. 7 is a flow chart of some embodiments illustrating a method of manufacturing a semiconductor device package in accordance with another aspect of the present disclosure. Referring to FIG. 7, the method 200 begins with the operation 110 in which a copper lead frame 10 and a copper oxide compound layer 20 are provided. In some embodiments, the copper oxide compound layer 20 is formed on the copper lead frame 10 by exposure to an oxygen-containing environment or by a front-end baking process, which is performed prior to provision of the semiconductor die 40 and the bonding wires 42. In some embodiments, the thickness of the copper oxide compound layer 20 is less than about 50 nanometers after exposure to the oxygen-containing environment or the front-end baking process, such as about 40 nanometers or less, about 30 nanometers or less, about 20 nanometers or less, or about 10 nanometers or less. In some embodiments, the thickness of the copper oxide compound layer 20 is about 10 nanometers after exposure to the oxygen-containing environment or the front-end baking process. The method proceeds with the operation 120 in which a semiconductor die 40 is disposed on the copper oxide compound layer 20. In some embodiments, bonding wires 42 are provided to electrically connect the semiconductor die 40 to the copper lead frame 10 through the copper oxide compound layer 20. In some embodiments, operations 110 and 120 are referred to as FE processes. The method proceeds with an operation 130 in which a baking process (a back-end baking process) is performed on the copper oxide compound layer 20. After the BE baking, the thickness of the copper oxide compound layer 20 may increase to be substantially equal to or larger than 50 nanometers, for example, may increase to be in a range from about 50 nanometers to about 100 nanometers. The method proceeds with the operation 150 in which an encapsulant 30 is formed over the copper oxide compound layer 20. In some embodiments, operations 130 and 150 are referred to as BE processes.

The method 200 is merely an example, and is not intended to limit the present disclosure. Additional operations can be provided before, during, and/or after the method 200, and some operations described can be replaced, eliminated, or re-ordered to provide for other embodiments of the method.

In some embodiments, the baking process is performed in a high temperature oxygen-containing environment such that more Cu (I) can be thermally oxidized to form CuO. In some embodiments (e.g. in the embodiments shown in FIG. 1), the amount of CuO of a first portion of the copper oxide compound layer 20 proximate to the surface 20S is higher than that of a second portion of the copper oxide compound layer 20 proximate to the surface 10S of the copper lead frame 10. CuO can provide for generation of more hydrogen bonds with hydrogen atoms of promotors such as silicon hydroxide (SiOH) in the encapsulant 30. Accordingly, adhesion strength between the copper lead frame 10 and the encapsulant 30 may be enhanced. In some embodiments, the thickness of the copper oxide compound layer 20 may be less than about 50 nanometers before performing the baking process, and a thickness uniformity of the copper oxide compound layer 20 may be less than desired. For example, the copper oxide compound layer 20 may be thinner in an edge portion than in a center portion. The BE baking process may increase the thickness of the copper oxide compound layer 20. By way of example, the thickness of the copper oxide compound layer 20 may be in a range from about 50 nanometers to about 100 nanometers after performing the BE baking process. In addition, the thickness uniformity of the copper oxide compound layer 20 may be improved as the thickness of the copper oxide compound layer 20 increases. In some embodiments, the ratio of CuO to Cu₂O of a first portion of the copper oxide compound layer 20 proximate to the surface 20S is higher than the ratio of CuO to Cu₂O of a second portion of the copper oxide compound layer 20 proximate to the surface 10S after the baking process. In some embodiments, the ratio of CuO to Cu₂O of the first portion of the copper oxide compound layer 20 proximate to the surface 20S is higher than that of the second portion of the copper oxide compound layer 20 proximate to the surface 10S both in the center portion and in the edge portion of the copper oxide compound layer 20 after performing the BE baking process.

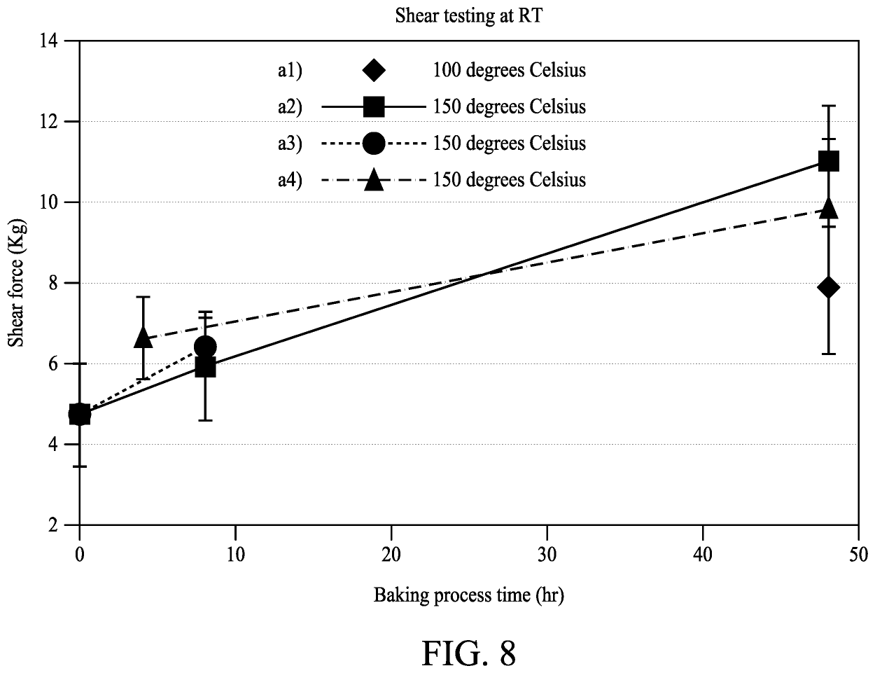

In some embodiments, the process temperature of the baking process is in a range from about 150° C. to about 250° C., and the baking process time of the baking process is less than or equal to about 48 hours (such as less than or equal to about 45 hours, less than or equal to about 42 hours, or less than or equal to about 39 hours), but not limited thereto. FIG. 8 shows an experimental result of shear forces at room temperature in accordance with another aspect of the present disclosure, wherein sample al includes semiconductor device packages that have undergone a BE baking process at about 100° C., sample includes are semiconductor device packages that have undergone a BE baking process at about 150° C., sample a3 includes semiconductor device packages that have undergone a BE baking process at about 160° C., and sample a4 includes semiconductor device packages that have undergone a BE baking process at about 170° C. As shown in FIG. 8, the experimental result shows that the shear force of the semiconductor device packages that have undergone a BE baking process at over about 150° C. tends to be higher than the shear force of the semiconductor device packages that have undergone a BE baking process at 100° C. The experimental result also shows that the shear force of the semiconductor device packages tends to increase when the baking process time increases.

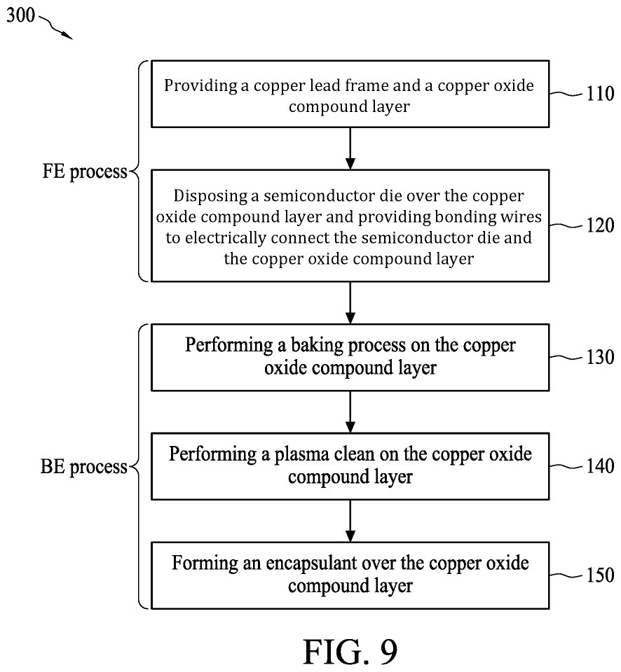

FIG. 9 is a flow chart of some embodiments illustrating a method of manufacturing a semiconductor device package in accordance with another aspect of the present disclosure. Referring to FIG. 9, the method 300 begins with the operation 110 in which a copper lead frame 10 and a copper oxide compound layer 20 are provided. In some embodiments, the copper oxide compound layer 20 is formed on the copper lead frame 10 by exposure to an oxygen-containing environment or by an FE baking process, which is performed prior to provision of the semiconductor die 40 and the bonding wires 42. In some embodiments, the thickness of the copper oxide compound layer 20 is less than about 50 nanometers after exposure to the oxygen-containing environment or the FE baking process, such as about 40 nanometers or less, about 30 nanometers or less, about 20 nanometers or less, or about 10 nanometers or less. In some embodiments, the thickness of the copper oxide compound layer 20 is about 10 nanometers after exposure to the oxygen-containing environment or the FE baking process. The method proceeds with the operation 120 in which a semiconductor die 40 is disposed on the copper oxide compound layer 20. In some embodiments, bonding wires 42 are provided to electrically connect the semiconductor die 40 to the copper lead frame 10 through the copper oxide compound layer 20. In some embodiments, operations 110 and 120 are referred to as FE processes. The method proceeds with the operation 130 in which a BE baking process is performed on the copper oxide compound layer 20. After the BE baking process, the thickness of the copper oxide compound layer 20 may increase to be substantially equal to or larger than about 50 nanometers, for example, may increase to be in a range from about 50 nanometers to about 100 nanometers. The method proceeds with the operation 140 in which a BE plasma clean is performed on the copper oxide compound layer 20. The method proceeds with the operation 150 in which an encapsulant 30 is formed over the copper oxide compound layer 20. In some embodiments, operations 130, 140 and 150 are referred to as BE processes.

The method 300 is merely an example, and is not intended to limit the present disclosure beyond what is explicitly recited in the claims. Additional operations can be provided before, during, and/or after the method 300, and some operations described can be replaced, eliminated, or re-ordered to provide for other embodiments of the method.

In some embodiments, the method 300 includes performing both the BE baking process and the BE plasma clean as illustrated in the aforementioned description, and detailed recipes are not redundantly described.

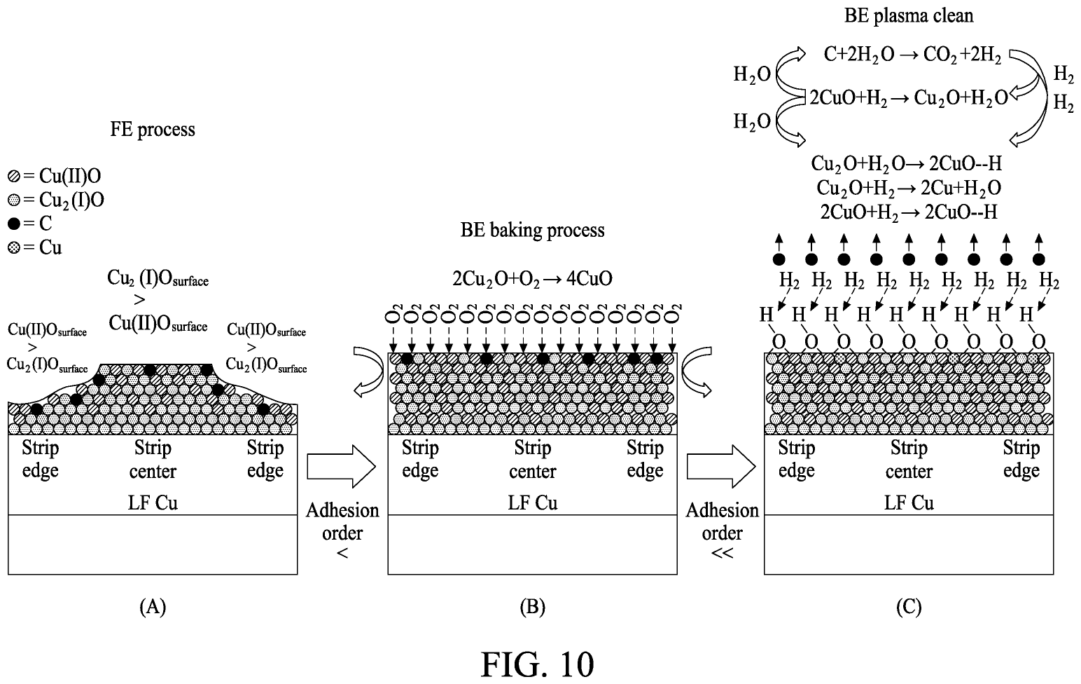

FIG. 10 is a schematic diagram of some embodiments illustrating a method of manufacturing a semiconductor device package in accordance with another aspect of the present disclosure. As shown in FIG. 10, at stage (A) the copper lead frame 10 is provided, and a copper oxide compound layer 20 is formed on the copper lead frame 10 (e.g. in an implementation of the operation 110). In some embodiments, the copper oxide compound layer 20 is formed on the copper lead frame 10 by exposure to an oxygen-containing environment or by an FE baking process. In some embodiments, the thickness of the copper oxide compound layer 20 is less than about 50 nanometers before performing the BE baking process, such as about 40 nanometers or less, about 30 nanometers or less, about 20 nanometers or less, or about 10 nanometers or less. In some embodiments, the thickness of the copper oxide compound layer 20 is about 10 nanometers before performing the BE baking process, and a thickness uniformity of the copper oxide compound layer 20 is less than desired. A semiconductor die (not shown) is provided on the copper oxide compound layer 20 (e.g. in an implementation of the operation 120). In some embodiments, an FE plasma clean may be performed. In some embodiments, bonding wires (not shown) may be provided (e.g. in an implementation of the operation 120). In some embodiments, the thickness of the copper oxide compound layer 20 has less than desired uniformity after the FE plasma clean. For example, a center portion of the copper oxide compound layer 20 is thicker (as illustrated in FIG. 10A), and the amount of Cu₂(I)O in the center portion is more than the amount of Cu(II)O in an edge portion of the copper oxide compound layer 20. The edge portion of the copper oxide compound layer 20 is thinner, and the amount of Cu(II)O in the edge portion is greater than the amount of Cu₂(I)O.

As shown in FIG. 10, at stage (B) a BE baking process is performed to thermally oxidize the copper oxide compound layer 20. In some embodiments, the thickness of the copper oxide compound layer 20 is increased to be in a range from about 50 nanometers to about 100 nanometers after the BE baking process. In some embodiments, the thickness uniformity of the copper oxide compound layer 20 is improved, and Cu₂(I)O adjacent to the exposed surface of the copper oxide compound layer 20 is oxidized to Cu(II)O after the BE baking process.

As shown in FIG. 10, at stage (C) a BE plasma clean is performed to activate the copper oxide compound layer 20. In some embodiments, the plasma clean is performed to form hydrogen bonds between Cu(II)O and hydrogen atoms from the promotors of an encapsulant (not shown).

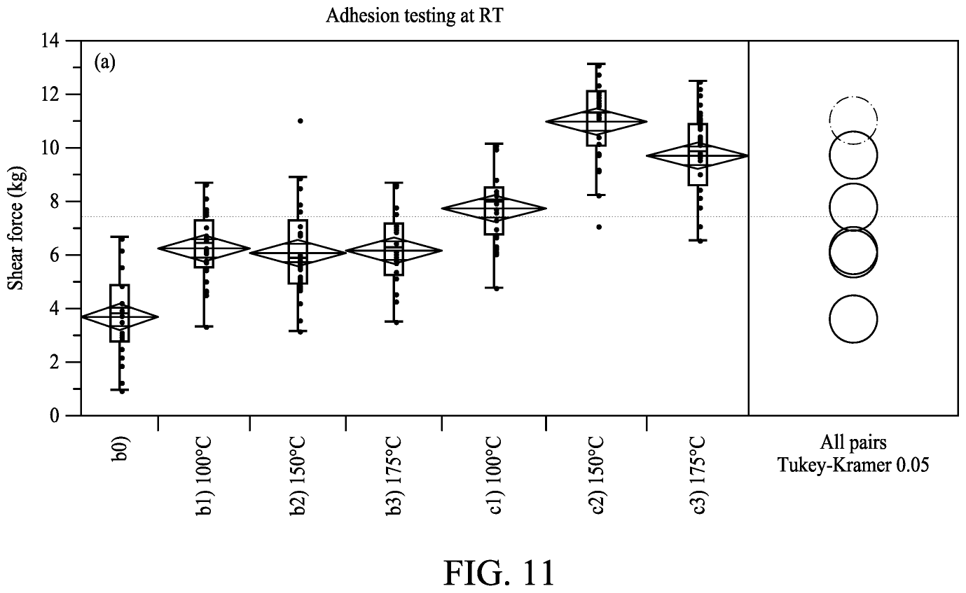

FIG. 11 shows an experimental result of shear forces at room temperature and corresponding all-pairs Tukey-Kramer data in accordance with another aspect of the present disclosure, wherein sample b0 includes semiconductor device packages that have not undergone a BE baking process, sample b1 includes semiconductor device packages that have undergone a BE baking process at about 100° C., sample b2 includes semiconductor device packages that have undergone a BE baking process at about 150° C., sample b3 includes semiconductor device packages that have undergone a BE baking process at about 175° C., sample c1 includes semiconductor device packages that have undergone a BE baking process at about 100° C. and a BE plasma clean, sample c2 includes semiconductor device packages that have undergone a BE baking process at about 150° C. and a BE plasma clean, and sample c3 includes semiconductor device packages that have undergone a BE baking process at about 175° C. and a BE plasma clean. As shown in FIG. 11, the experimental result shows that the shear force of the semiconductor device packages that have undergone a baking process at over about 150° C. tends to be higher than the shear force of the semiconductor device packages that have undergone a baking process at about 100° C. The experimental result also shows that the shear force of the semiconductor device packages that have undergone both a BE baking process and a BE plasma clean tends to be further increased in comparison to the shear force of the semiconductor device packages that have undergone a BE baking process but without a BE plasma clean.

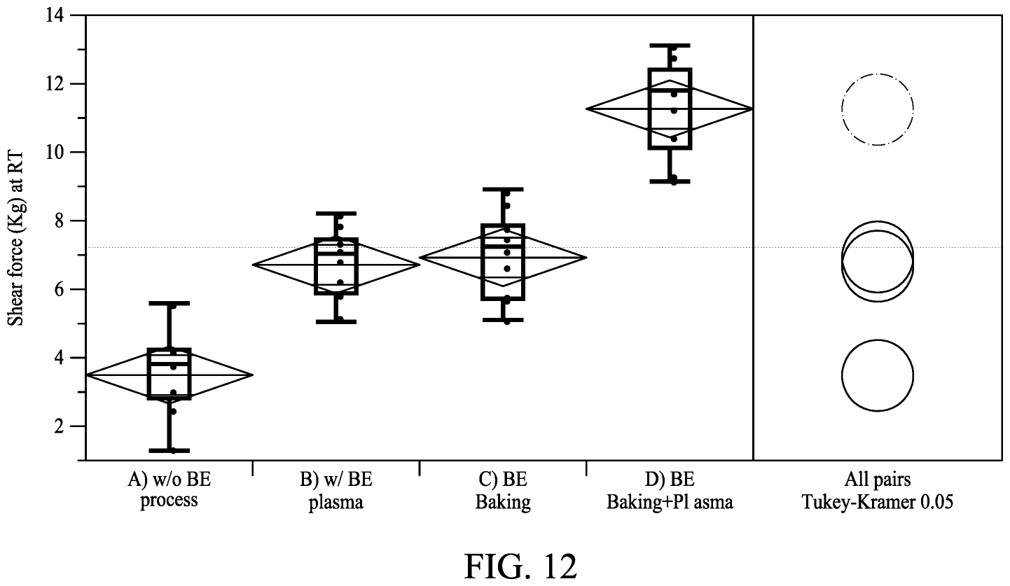

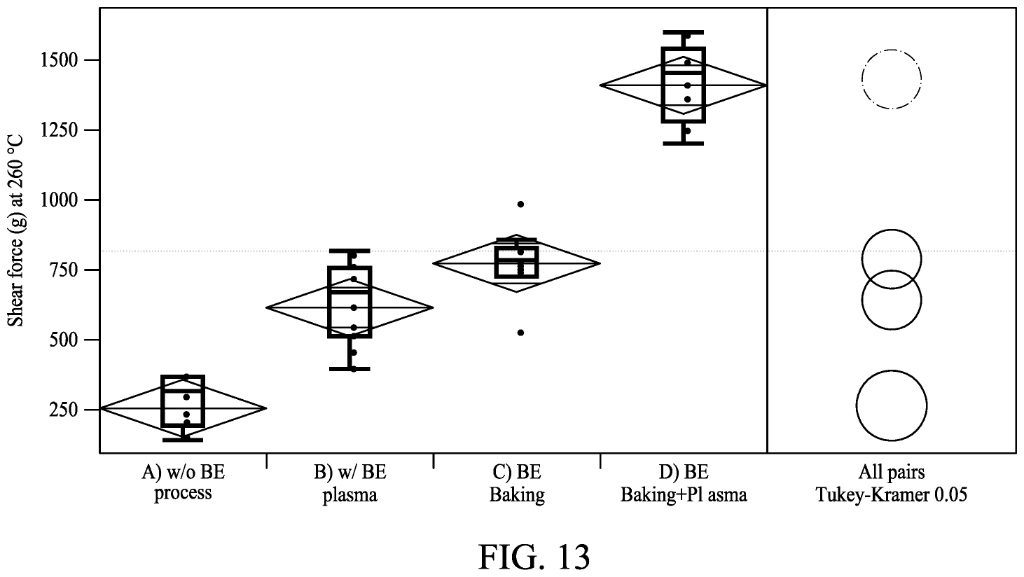

Referring to FIG. 12, FIG. 13 and Table 1 (provided below, in-text), FIG. 12 shows an experimental result of shear forces at room temperature and corresponding all-pairs Tukey-Kramer data in accordance with another aspect of the present disclosure, and FIG. 13 shows an experimental result of shear forces at high temperature and corresponding all-pairs Tukey-Kramer data in accordance with another aspect of the present disclosure, and Table 1 lists the thickness of the copper oxide compound layer and corresponding shear force of the experimental result. In the experiment, sample A includes semiconductor device packages that have not undergone a BE baking process and a BE plasma clean, sample B includes semiconductor device packages that have undergone a BE plasma clean, sample C includes semiconductor device packages that have undergone a BE baking process, and sample D includes semiconductor device packages that have undergone a BE baking process and a BE plasma clean. As shown in FIG. 12 and in FIG. 13, the experimental results show that the shear force of the semiconductor device packages that have undergone at least one of, or both of, a BE plasma clean and a BE baking process is larger than the shear force of the semiconductor device packages that have not undergone either the BE baking process or the BE plasma clean, whether tested at room temperature or higher temperature (e.g. at about 260° C. or higher).

TABLE 1

| | | | BE | Copper oxide | | |
|---|---|---|---|---|---|---|
| | FE | BE | Plasma | compound layer | Shear | |
| | Process | baking | clean | thickness | force | |
| A | Yes | | | about 10 nm | <4 | kg |
| B | Yes | | Yes | about 10 nm | >6 | kg |
| C | Yes | Yes | | about 65 nm | >7 | kg |
| D | Yes | Yes | Yes | about 70 nm | >11 | kg |

In some embodiments of the present disclosure, the semiconductor device package includes a copper oxide compound layer including Cu(II) oxide (CuO) and Cu(I) oxide (Cu₂O), and the ratio of Cu(II) oxide to Cu(I) oxide is equal to or greater than about 1. In some embodiments, the ratio of Cu(II) oxide to Cu(I) oxide of a first portion of the copper oxide compound layer proximate to an interface between an encapsulant and the copper oxide compound layer is greater than that of a second portion of the copper oxide compound layer distant from the interface relative to the first portion. As discussed above, in some implementations, the copper oxide compound layer including Cu(II) oxide and Cu(I) oxide provides for significantly increased adhesion strength of the copper lead frame to the encapsulant, as compared to some comparative implementations. The semiconductor device package of the present disclosure provides for some advantages such as being unlikely to delaminate and its high reliability.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method for manufacturing a semiconductor device package, comprising:
providing a copper lead frame;
forming a copper oxide compound layer on a surface of the copper lead frame;
disposing a semiconductor die on the copper oxide compound layer;
performing a surface activation treatment on the copper oxide compound layer subsequent to disposing the semiconductor die on the copper oxide compound layer; and
forming an encapsulant on the copper oxide compound layer.

2. The method of claim 1, wherein the copper oxide compound layer is formed on the surface of the copper lead frame by a front end baking process.

3. The method of claim 1, wherein the copper oxide compound layer comprises copper(II) oxide and copper(I) oxide, and the surface activation treatment is configured to increase an amount of copper(II) oxide in the copper oxide compound layer.

4. The method of claim 3, wherein a ratio of Copper(II) to Copper(I) of the copper oxide compound layer is equal to or greater than 1 after the surface activation treatment.

5. The method of claim 1, wherein the surface activation treatment comprises performing a plasma clean.

6. The method of claim 5, further comprising introducing hydrogen gas during the plasma clean.

7. The method of claim 5, wherein a plasma process time of the plasma clean is between about 10 seconds and about 600 seconds, and a power of the plasma clean is between about 50 watts and about 1200 watts.

8. The method of claim 1, wherein the surface activation treatment comprises performing a back end baking process.

9. The method of claim 8, wherein a process temperature of the back end baking process is between about 150° C. to about 250° C., and a process time of the back end baking process is less than or equal to about 48 hours.

10. The method of claim 1, wherein the surface activation treatment comprises performing a back end baking process and a plasma clean.
